(19) United States
(12) Patent Application Publication
(10) Pub. No.: US 2025/0241012 A1
(43) Pub. Date: Jul. 24, 2025

(54) SEMICONDUCTOR DEVICE

(71) Applicant: Samsung Electronics Co., Ltd., Suwon-si (KR)

(72) Inventors: Sang Hee LEE, Suwon-si (KR); Heon Jong SHIN, Suwon-si (KR); Seo Woo NAM, Suwon-si (KR)

(73) Assignee: Samsung Electronics Co., Ltd., Suwon-si (KR)

(21) Appl. No.: 18/797,049

(22) Filed: Aug. 7, 2024

(30) Foreign Application Priority Data
Jan. 23, 2024 (KR) 10-2024-0009905

(51) Int. Cl. H01L 29/786; H01L 21/8234; H01L 23/522; H01L 27/088; H01L 29/06; H01L 29/08; H01L 29/423; H01L 29/66; H01L 29/775

(52) U.S. Cl. CPC H10D 30/6757; H01L 23/5226; H10D 30/014; H10D 30/43; H10D 30/6735; H10D 62/121; H10D 62/151; H10D 64/017; H10D 84/013; H10D 84/0149; H10D 84/038; H10D 84/83

(57) ABSTRACT

A semiconductor device includes a lower interlayer insulating layer, an insulating pattern extending in a first horizontal direction on a top surface of the lower interlayer insulating layer, first, second, and third gate electrodes extending in a second horizontal direction and arranged in the first horizontal direction, a first source/drain region between the first and second gate electrodes and a second source/drain region between the second and third gate electrodes on the insulating pattern, a lower source/drain contact extending into the second source/drain region by vertically penetrating the lower interlayer insulating layer and the insulating pattern, a top of the lower source/drain contact being higher than a top surface of the insulating pattern, a first insulating liner layer on both sidewalls of the lower source/drain contact, and a lower silicide layer between the second source/drain region and the lower source/drain contact.

### CROSS-REFERENCE TO RELATED APPLICATION

This application claims priority from Korean Patent Application No. 10-2024-0009905 filed on Jan. 23, 2024 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to semiconductor devices, and more particularly, to semiconductor devices including a multi-bridge channel field-effect transistor (MBCFET™).

### 2. Description of the Related Art

As a scaling technique for increasing the density of integrated circuit devices, the concept of a multi-gate transistor has been proposed in which a silicon body in the form of a fin or nanowire is formed on a substrate and a gate is formed on the surface of the silicon body.

The multi-gate transistor takes advantage of its three-dimensional (3D) channel, allowing for easy scaling both up and down. Additionally, the multi-gate transistor offers improved control over the current without the need to increase the gate length. Furthermore, the multi-gate transistor effectively mitigates the short channel effect (SCE), which is the phenomenon where the electric potential of a channel region is affected by the drain voltage.

### SUMMARY

Some example embodiments of the present disclosure provide semiconductor devices capable of improving reliability of the electrical connection between source/drain contacts disposed in a backside region and source/drain regions.

However, example embodiments of the present disclosure are not restricted to those set forth herein. The above and other example embodiments of the present disclosure will become more apparent to one of ordinary skill in the art to which the present disclosure pertains by referencing the detailed description of the present disclosure given below.

According to an example embodiment of the present disclosure, a semiconductor device may include a first lower interlayer insulating layer, an insulating pattern extending in a first horizontal direction on a top surface of the first lower interlayer insulating layer, first, second, and third gate electrodes extending in a second horizontal direction different from the first horizontal direction on the insulating pattern, the first, second, and third gate electrodes being sequentially spaced apart from one another in the first horizontal direction, a first source/drain region between the first and second gate electrodes on the insulating pattern, a second source/drain region between the second and third gate electrodes on the insulating pattern, a lower source/drain contact extending into the second source/drain region by penetrating the first lower interlayer insulating layer and the insulating pattern in a vertical direction, a top surface of the lower source/drain contact being higher than a top surface of the insulating pattern, a first insulating liner layer between the lower source/drain contact and each of the first lower interlayer insulating layer and the insulating pattern, and a lower silicide layer between the second source/drain region and the lower source/drain contact, the lower silicide layer being in contact with a top surface of the first insulating liner layer.

According to an example embodiment of the present disclosure, a semiconductor device may include a first lower interlayer insulating layer, an insulating pattern extending in a first horizontal direction on a top surface of the first lower interlayer insulating layer, a first plurality of nanosheets stacked to be spaced apart from one another in a vertical direction on the insulating pattern, a second plurality of nanosheets stacked to be spaced apart from one another in the vertical direction on the insulating pattern, the second plurality of nanosheets spaced apart from the first plurality of nanosheets in the first horizontal direction, a first gate electrode extending in a second horizontal direction different from the first horizontal direction on the insulating pattern, the first gate electrode surrounding the first plurality of nanosheets, a second gate electrode extending in the second horizontal direction on the insulating pattern, the second gate electrode spaced apart from the first gate electrode in the first horizontal direction, the second gate electrode surrounding the second plurality of nanosheets, a source/drain region between the first and second gate electrodes on the insulating pattern, a lower source/drain contact extending into the source/drain region by penetrating the first lower interlayer insulating layer and the insulating pattern in the vertical direction, a top of the lower source/drain contact being higher than a top surface of a lowermost nanosheet of the first plurality of nanosheets, a first insulating liner layer between the lower source/drain contact and each of the first lower interlayer insulating layer and the insulating pattern, and a lower via below the lower source/drain contact, a width of a top surface of the lower via in the first horizontal direction being greater than a width of a bottom surface of the lower source/drain contact in the first horizontal direction, at least part of the top surface of the lower via being in contact with the first lower interlayer insulating layer.

According to an example embodiment of the present disclosure, a semiconductor device may include a first lower interlayer insulating layer, an insulating pattern extending in a first horizontal direction on a top surface of the first lower interlayer insulating layer, a first plurality of nanosheets stacked to be spaced apart from one another in a vertical direction on the insulating pattern, a second plurality of nanosheets stacked to be spaced apart from one another in the vertical direction on the insulating pattern, the second plurality of nanosheets spaced apart from the first plurality of nanosheets in the first horizontal direction, a third plurality of nanosheets stacked to be spaced apart from one another in the vertical direction on the insulating pattern, the third plurality of nanosheets spaced apart from the second plurality of nanosheets in the first horizontal direction, a first gate electrode extending in a second horizontal direction different from the first horizontal direction on the insulating pattern, the first gate electrode surrounding the first plurality of nanosheets, a second gate electrode extending in the second horizontal direction on the insulating pattern, the second gate electrode spaced apart from the first gate electrode in the first horizontal direction, the second gate electrode surrounding the second plurality of nanosheets, a third gate electrode extending in the second horizontal direction on the insulating pattern, the third gate electrode spaced apart from the second gate electrode in the first horizontal direction, the third gate electrode surrounding the third plurality of nanosheets, a first source/drain region between the first and second gate electrodes on the insulating pattern, a second source/drain region between the second and third gate electrodes on the insulating pattern, an upper interlayer insulating layer covering the first and second source/drain regions on the top surface of the first lower interlayer insulating layer, an upper source/drain contact extending into the first source/drain region by penetrating the upper interlayer insulating layer in the vertical direction, a lower source/drain contact extending into the second source/drain region by penetrating the first lower interlayer insulating layer and the insulating pattern in the vertical direction, a top of the lower source/drain contact being higher than a top surface of a lowermost nanosheet of the second plurality of nanosheets, a lower via below the lower source/drain contact, a width of a top surface of the lower via in the first horizontal direction being greater than a bottom surface of the lower source/drain contact in the first horizontal direction, a first insulating liner layer between the lower source/drain contact and each of the first lower interlayer insulating layer and the insulating pattern, a second insulating liner layer being in contact with both sidewalls of the lower via in the first horizontal direction, the second insulating liner layer including a same material as the first insulating liner layer, and a lower silicide layer between the second source/drain region and the lower source/drain contact, the lower silicide layer being in contact with a top surface of the first insulating liner layer.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail example embodiments thereof with reference to the attached drawings, in which:

FIG. 1 is a layout view for explaining a semiconductor device according to an example embodiment of the present disclosure;

FIG. 2 is a cross-sectional view taken along line A-A′ of FIG. 1;

FIG. 3 is a cross-sectional view taken along line B-B′ of FIG. 1;

FIGS. 4 through 24 are cross-sectional views for explaining intermediate steps of a method of fabricating a semiconductor device according to an example embodiment of the present disclosure;

FIG. 25 is a cross-sectional view for explaining a semiconductor device according to an example embodiment of the present disclosure;

FIG. 26 is a cross-sectional view for explaining a semiconductor device according to an example embodiment of the present disclosure;

FIG. 27 is a cross-sectional view for explaining a semiconductor device according to an example embodiment of the present disclosure; and

FIG. 28 is a cross-sectional view for explaining a semiconductor device according to an example embodiment of the present disclosure.

### DETAILED DESCRIPTION

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

Semiconductor devices according to some example embodiments of the present disclosure are illustrated in the accompanying drawings as including multi-bridge channel field-effect transistors (MBCFETs™) with nanosheets, but example embodiments of the present disclosure are not limited thereto. In other example embodiments, semiconductor devices may include fin-type field-effect transistors (FinFETs) with fin-shaped pattern channel regions, tunneling field-effect transistors (FETs), or three-dimensional (3D) transistors. Furthermore, in yet other embodiments, semiconductor devices may include bipolar junction transistors or lateral double-diffused metal-oxide semiconductor (LDMOS) transistors.

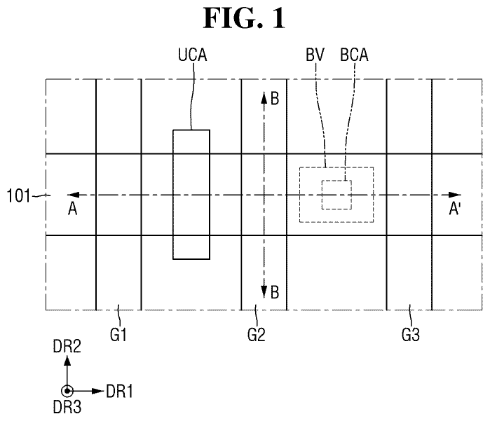

A semiconductor device according to an example embodiment of the present disclosure will hereinafter be described with reference to FIGS. 1 through 3.

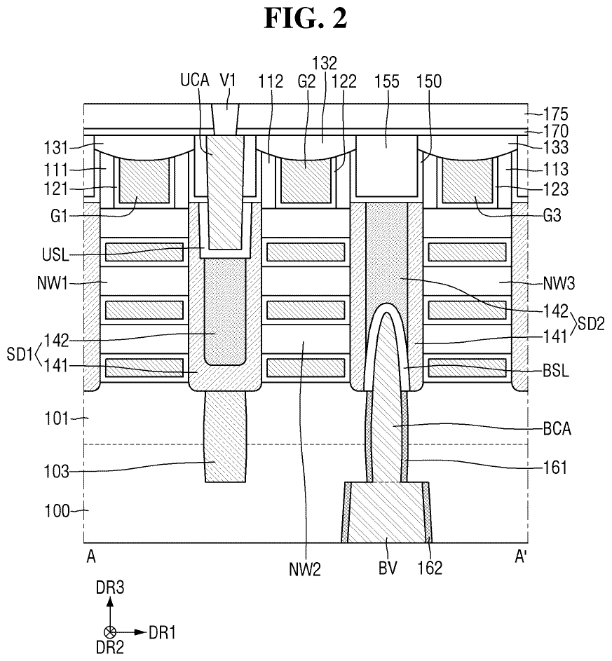

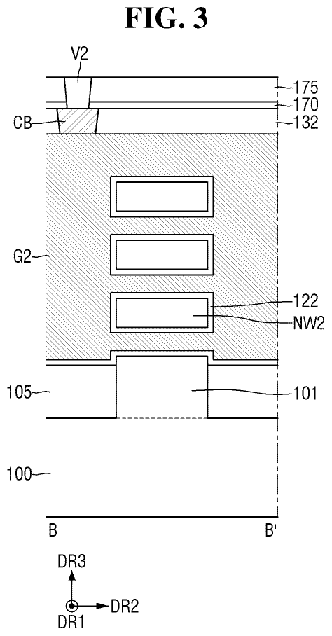

FIG. 1 is a layout view for explaining a semiconductor device according to an example embodiment of the present disclosure. FIG. 2 is a cross-sectional view taken along line A-A′ of FIG. 1. FIG. 3 is a cross-sectional view taken along line B-B′ of FIG. 1.

Referring to FIGS. 1 through 3, the semiconductor device according to an example embodiment of the present disclosure includes a first lower interlayer insulating layer 100, an insulating pattern 101, a first sacrificial pattern 103, a field insulating layer 105, first plurality of nanosheets NW1, second plurality of nanosheets NW2, third plurality of nanosheets NW3, first, second, and third gate electrodes G1, G2, and G3, first gate spacers 111, second gate spacers 112, and third gate spacers 113, first, second, and third gate insulating layers 121, 122, and 123, first, second, and third capping patterns 131, 132, and 133, first and second source/drain regions SD1 and SD2, a first etching stop layer 150, a first upper interlayer insulating layer 155, a gate contact CB, an upper source/drain contact UCA, a lower source/drain contact BCA, an upper silicide layer USL, a lower silicide layer BSL, a lower via BV, first and second insulating liner layers 161 and 162, a second etching stop layer 170, a second upper interlayer insulating layer 175, and first and second vias V1 and V2.

The first lower interlayer insulating layer 100 may include, for example, at least one of silicon oxide, silicon nitride, silicon oxynitride, or a low-k material. The low-k material may be, for example, fluorinated tetraethyl orthosilicate (FTEOS), hydrogen silsesquioxane (HSQ), bis-benzocyclobutene (BCB), tetramethyl orthosilicate (TMOS), octamethylcyclotetrasiloxane (OMCTS), hexamethyldisiloxane (HMDS), trimethylsilyl borate (TMSB), diacetoxy ditertiary butoxy siloxane (DADBS), trimethylsilil phosphate (TMSP), polytetrafluoroethylene (PTFE), tonen silazen (TOSZ), fluoride silicate glass (FSG), polyimide nanofoam such as polypropylene oxide, carbon doped silicon oxide (CDO), organo silicate glass (OSG), SiLK, amorphous fluorinated carbon, silica aerogel, silica xerogel, mesoporous silica, or a combination thereof, but example embodiments of the present disclosure are not limited thereto.

First and second horizontal directions DR1 and DR2 may be defined as directions parallel to the top surface of the first lower interlayer insulating layer 100. The second horizontal direction DR2 may be defined as a different direction from the first horizontal direction DR1. A vertical direction DR3 is defined as a direction perpendicular to both the first and second horizontal directions DR1 and DR2. That is, the vertical direction DR3 is defined as a direction perpendicular to the top surface of the first lower interlayer insulating layer 100.

The insulating pattern 101 may extend in the first horizontal direction DR1 on the top surface of the first lower interlayer insulating layer 100. The insulating pattern 101 may protrude in the vertical direction DR3 from the top surface of the first lower interlayer insulating layer 100. The insulating pattern 101 may include an insulating material. For example, the insulating pattern 101 may include the same material as the first lower interlayer insulating layer 100.

The field insulating layer 105 may be disposed on the top surface of the first lower interlayer insulating layer 100. The field insulating layer 105 may surround the sidewalls of the insulating pattern 101. For example, the top surface of the insulating pattern 101 may protrude in the vertical direction DR3 beyond the top surface of the field insulating layer 105, but example embodiments of the present disclosure are not limited thereto. In other example embodiments, the top surface of the insulating pattern 101 may be formed on the same plane as the top surface of the field insulating layer 105. The field insulating layer 105 may include, for example, an oxide film, a nitride film, an oxynitride film, or a combination thereof.

The first plurality of nanosheets NW1 may be disposed on the insulating pattern 101. The first plurality of nanosheets NW1 may be disposed at the intersection of the insulating pattern 101 and the first gate electrode G1. The second plurality of nanosheets NW2 may be disposed on the insulating pattern 101. The second plurality of nanosheets NW2 may be disposed at the intersection of the insulating pattern 101 and the second gate electrode G2. The second plurality of nanosheets NW2 may be spaced apart from the first plurality of nanosheets NW1 in the first horizontal direction DR1. The third plurality of nanosheets NW3 may be disposed on the insulating pattern 101. The third plurality of nanosheets NW3 may be disposed at the intersection of the insulating pattern 101 and the third gate electrode G3. The third plurality of nanosheets NW3 may be spaced apart from the second plurality of nanosheets NW2 in the first horizontal direction DR1.

The first plurality of nanosheets NW1, the second plurality of nanosheets NW2, and the third plurality of nanosheets NW3 each may include a stack of plurality of nanosheets that are vertically spaced apart in the vertical direction DR3. In FIGS. 2 and 3, the first plurality of nanosheets NW1, the second plurality of nanosheets NW2, and the third plurality of nanosheets NW3 are illustrated as including stacks of three nanosheets that are stacked in the vertical direction DR3 to be apart from one another, but example embodiments of the present disclosure are not limited thereto. In some example embodiments, the first plurality of nanosheets NW1, the second plurality of nanosheets NW2, and the third plurality of nanosheets NW3 each may include more than four stacks of nanosheets that are stacked in the vertical direction DR3 to be apart from one another. For example, the first plurality of nanosheets NW1, the second plurality of nanosheets NW2, and the third plurality of nanosheets NW3 may include silicon (Si), but example embodiments of the present disclosure are not limited thereto. In some example embodiments, the first plurality of nanosheets NW1, the second plurality of nanosheets NW2, and the third plurality of nanosheets NW3 may include silicon germanium (SiGe).

The first gate electrode G1 may extend in the second horizontal direction DR2 over the insulating pattern 101 and the field insulating layer 105. The first gate electrode G1 may surround the first plurality of nanosheets NW1. The second gate electrode G2 may extend in the second horizontal direction DR2 over the insulating pattern 101 and the field insulating layer 105. The second gate electrode G2 may surround the second plurality of nanosheets NW2. The second gate electrode G2 may be spaced apart from the first gate electrode G1 in the first horizontal direction DR1. The third gate electrode G3 may extend in the second horizontal direction DR2 over the insulating pattern 101 and the field insulating layer 105. The third gate electrode G3 may surround the third plurality of nanosheets NW3. The third gate electrode G3 may be spaced apart from the second gate electrode G2 in the first horizontal direction DR1.

The first, second, and third gate electrodes G1, G2, and G3 may include, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel-platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or a combination thereof. The first, second, and third gate electrodes G1, G2, and G3 may include a conductive metal oxide or conductive metal oxynitride, and may also include an oxidized form of any one of the aforementioned materials.

The first gate spacers 111 may extend in the second horizontal direction DR2 along both sidewalls of the first gate electrode G1 on the top surface of the uppermost nanosheet of the first plurality of nanosheets NW1 and on the field insulating layer 105. The second gate spacers 112 may extend in the second horizontal direction DR2 along both sidewalls of the second gate electrode G2 on the top surface of the uppermost nanosheet of the second plurality of nanosheets NW2 and on the field insulating layer 105. The third gate spacers 113 may extend in the second horizontal direction DR2 along both sidewalls of the third gate electrode G3 on the top surface of the uppermost nanosheet of the third plurality of nanosheets NW3 and on the field insulating layer 105.

The first gate spacers 111, the second gate spacers 112, and the third gate spacers 113 may include at least one of silicon nitride (SiN), silicon oxide (SiO₂), silicon oxycarbonitride (SiOCN), silicon boron nitride (SiBN), silicon oxyboron nitride (SiOBN), silicon oxycarbide (SiOC), or a combination thereof, but example embodiments of the present disclosure are not limited thereto.

The first source/drain region SD1 may be disposed on either side of the first gate electrode G1 on the insulating pattern 101. For example, the first source/drain region SD1 may be disposed between the first and second gate electrodes G1 and G2 on the insulating pattern 101. The second source/drain regions SD2 may be disposed on either side of the third gate electrode G3 on the insulating pattern 101. For example, the second source/drain regions SD2 may be disposed between the second and third gate electrodes G2 and G3 on the insulating pattern 101.

Each of the first and second source/drain regions SD1 and SD2 may be in contact with the insulating pattern 101. The first source/drain region SD1 may be in contact with the sidewalls of the first plurality of nanosheets NW1 and the sidewalls of the second plurality of nanosheets NW2 in the first horizontal direction DR1. The second source/drain region SD2 may be in contact with the sidewalls of the second plurality of nanosheets NW2 and the third plurality of nanosheets NW3 in the first horizontal direction DR1. For example, the top surfaces of the first and second source/drain regions SD1 and SD2 may be formed higher than the top surfaces of the uppermost nanosheets of the first, second, and third plurality of nanosheets NW1, NW2, and NW3.

For example, each of the first and second source/drain regions SD1 and SD2 may include first and second layers 141 and 142. For example, the first layer 141 may be in contact with both sidewalls, in the first horizontal direction DR1, of each of the first plurality of nanosheets NW1, the second plurality of nanosheets NW2, and the third plurality of nanosheets NW3 and the top surface of the insulating pattern 101. The second layer 142 may be disposed on the first layer 141. For example, the first and second layers 141 and 142 may include SiGe. For example, the concentration of germanium (Ge) in the second layer 142 may be greater than the concentration of Ge in the first layer 141.

The first sacrificial pattern 103 may be disposed below the first source/drain region SD1. The first sacrificial pattern 103 may be in contact with the bottom surface of the first source/drain region SD1. For example, the first sacrificial pattern 103 may be in contact with the first layer 141. The first sacrificial pattern 103 may extend into the first lower interlayer insulating layer 100 through the insulating pattern 101 in the vertical direction DR3. For example, both sidewalls, in the first horizontal direction DR1, of the first sacrificial pattern 103 may be in contact with the insulating pattern 101 and the first lower interlayer insulating layer 100. Additionally, the bottom surface of the first sacrificial pattern 103 may be in contact with the first lower interlayer insulating layer 100.

The first sacrificial pattern 103 may include a different material from each of the first lower interlayer insulating layer 100 and the insulating pattern 101. For example, the first sacrificial pattern 103 may include SiGe. The concentration of Ge in the first sacrificial pattern 103 may be greater than the concentration of Ge in the first layer 141. Further, the concentration of Ge in the first sacrificial pattern 103 may be less than the concentration of Ge in the second layer 142. For example, the width, in the first horizontal direction DR1, of the first sacrificial pattern 103 may be less than the width, in the first horizontal direction DR1, of the first source/drain region SD1.

The first gate insulating layer 121 may be disposed between the first gate electrode G1 and the insulating pattern 101. The first gate insulating layer 121 may also be disposed between the first gate electrode G1 and the field insulating layer 105. The first gate insulating layer 121 may also be disposed between the first gate electrode G1 and the first gate spacers 111. The first gate insulating layer 121 may also be disposed between the first gate electrode G1 and the first plurality of nanosheets NW1. The first gate insulating layer 121 may also be disposed between the first gate electrode G1 and the first source/drain region SD1.

The second gate insulating layer 122 may be disposed between the second gate electrode G2 and the insulating pattern 101. The second gate insulating layer 122 may also be disposed between the second gate electrode G2 and the field insulating layer 105. The second gate insulating layer 122 may also be disposed between the second gate electrode G2 and the second gate spacers 112. The second gate insulating layer 122 may also be disposed between the second gate electrode G2 and the second plurality of nanosheets NW2. The second gate insulating layer 122 may also be disposed between the second gate electrode G2 and each of the first and second source/drain regions SD1 and SD2.

The third gate insulating layer 123 may be disposed between the third gate electrode G3 and the insulating pattern 101. The third gate insulating layer 123 may also be disposed between the third gate electrode G3 and the field insulating layer 105. The third gate insulating layer 123 may also be disposed between the third gate electrode G3 and the third gate spacers 113. The third gate insulating layer 123 may also be disposed between the third gate electrode G3 and the third plurality of nanosheets NW3. The third gate insulating layer 123 may also be disposed between the third gate electrode G3 and the second source/drain region SD2.

Each of the first, second, and third gate insulating layers 121, 122, and 123 may be in contact with the insulating pattern 101. For example, the first and second gate insulating layers 121 and 122 may be in contact with the first source/drain region SD1. Additionally, the second and third gate insulating layers 122 and 123 may be in contact with the second source/drain region SD2. However, the present disclosure is not limited to this. In some example embodiments, inner spacers may be disposed between the first source/drain region SD1 and the first and second gate insulating layers 121 and 122 and between the second source/drain region SD2 and the second and third gate insulating layers 122 and 123. The inner spacers may include, for example, at least one of SiN, SiON, SiO₂, SiOCN, SiBN, SiOBN, SiOC, and a combination thereof.

The first, second, and third gate insulating layers 121, 122, and 123 may include at least one of silicon oxide, silicon oxynitride, silicon nitride, or a high-k material with a greater dielectric constant than silicon oxide. The high-k material may include, for example, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The semiconductor device according to some example embodiments of the present disclosure may include negative capacitance (NC) FETs using negative capacitors. For example, each of the first, second, and third gate insulating layers 121, 122, and 123 may include a ferroelectric material film having ferroelectric properties and a paraelectric material film having paraelectric properties.

The ferroelectric material film may have a negative capacitance, and the paraelectric material film may have a positive capacitance. For example, if two or more capacitors are connected in series and have positive capacitance, the total capacitance of the two or more capacitors may be lower than the capacitance of each of the two or more capacitors. On the contrary, if at least one of the two or more capacitors has negative capacitance, the total capacitance of the two or more capacitors may have a positive value and may be greater than the absolute value of the capacitance of each of the two or more capacitors.

If the ferroelectric material film having a negative capacitance and the paraelectric material film having a positive capacitance are connected in series, the total capacitance of the ferroelectric material film and the paraelectric material film may increase. Accordingly, a transistor having the ferroelectric material film may have a sub-threshold swing (SS) of less than about 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide, or lead zirconium titanium oxide. For example, the hafnium zirconium oxide may be a material obtained by doping hafnium oxide with zirconium (Zr). In another example, the hafnium zirconium oxide may be a compound of hafnium (Hf), Zr, and oxygen (O).

The ferroelectric material film may further include a dopant. For example, the dopant may include at least one of Al, Ti, Nb, lanthanum (La), yttrium (Y), magnesium (Mg), Si, calcium (Ca), cerium (Ce), dysprosium (Dy), erbium (Er), gadolinium (Gd), Ge, scandium (Sc), strontium (Sr), or Sn. The type of dopant may vary depending on the type of material of the ferroelectric material film.

If the ferroelectric material film includes hafnium oxide, the dopant of the ferroelectric material film may include, for example, at least one of Gd, Si, Zr, Al, or Y.

If the dopant of the ferroelectric material film is Al, the ferroelectric material film may include about 3 atomic % (at %) to about 8 at % of Al. Here, the ratio of the dopant in the ferroelectric material film may refer to the ratio of an amount of Al to the sum of the amounts of Hf and Al in the ferroelectric material film.

If the dopant of the ferroelectric material film is Si, the ferroelectric material film may include about 2 at % to about 10 at % of Si. If the dopant of the ferroelectric material film is Y, the ferroelectric material film may include about 2 at % to about 10 at % of Y. If the dopant of the ferroelectric material film is Gd, the ferroelectric material film may include about 1 at % to about 7 at % of Gd. If the dopant of the ferroelectric material film is Zr, the ferroelectric material film may include about 50 at % to about 80 at % of Zr.

The paraelectric material film may include paraelectric properties. The paraelectric material film may include, for example, at least one of silicon oxide or a high-k metal oxide. The high-k metal oxide may include, for example, at least one of hafnium oxide, zirconium oxide, or aluminum oxide, but example embodiments of the present disclosure are not limited thereto.

The ferroelectric material film and the paraelectric material film may include the same material. The ferroelectric material film may have ferroelectric properties, but the paraelectric material film may not have ferroelectric properties. For example, if the ferroelectric material film and the paraelectric material film include hafnium oxide, the hafnium oxide included in the ferroelectric material film may have a different crystalline structure from the hafnium oxide included in the paraelectric material film.

The ferroelectric material film may be thick enough to exhibit ferroelectric properties. The ferroelectric material film may have a thickness of, for example, about 0.5 nm to about 10 nm, but example embodiments of the present disclosure are not limited thereto. A critical thickness that may exhibit ferroelectric properties may vary depending on the type of ferroelectric material, and thus, the thickness of the ferroelectric material film may vary depending on the type of ferroelectric material included in the ferroelectric material film.

For example, each of the first, second, and third gate insulating layers 121, 122, and 123 may include a ferroelectric material film. In another example, each of the first, second, and third gate insulating layers 121, 122, and 123 may include a plurality of ferroelectric material films that are spaced apart from each other. Each of the first, second, and third gate insulating layers 121, 122, and 123 may include a stack of a plurality of ferroelectric material films and a plurality of paraelectric material films that are alternately stacked with the ferroelectric material films.

The first etching stop layer 150 may be disposed on the sidewalls, in the first horizontal direction DR1, of each of the first gate spacers 111, second gate spacers 112, and third gate spacers 113. The first etching stop layer 150 may also be disposed on the top surfaces of the first and second source/drain regions SD1 and SD2. Although not illustrated, the first etching stop layer 150 may be disposed on the sidewalls, in the second horizontal direction DR2, of each of the first and second source/drain regions SD1 and SD2. For example, the first etching stop layer 150 may be conformally formed. The first etching stop layer 150 may include, for example, at least one of aluminum oxide, aluminum nitride, hafnium oxide, zirconium oxide, silicon oxide, silicon nitride, silicon oxynitride, or a low-k material.

The first capping pattern 131 may extend in the second horizontal direction DR2 over each of the first gate spacers 111, the first gate insulating layer 121, and the first gate electrode G1. The second capping pattern 132 may extend in the second horizontal direction DR2 over each of the second gate spacers 112, the second gate insulating layer 122, and the second gate electrode G2. The third capping pattern 133 may extend in the second horizontal direction DR2 over each of the third gate spacers 113, the third gate insulating layer 123, and the third gate electrode G3.

For example, the bottom surfaces of the first, second, and third capping patterns 131, 132, and 133 may be in contact with the first etching stop layer 150, but example embodiments of the present disclosure are not limited thereto. In some example embodiments, the sidewalls of each of the first, second, and third capping patterns 131, 132, and 133 may also be in contact with the first etching stop layer 150. The first, second, and third capping patterns 131, 132, and 133 may include, for example, at least one of SiN, SiON, SiO₂, SiCN, SiOCN, or a combination thereof, but example embodiments of the present disclosure are not limited thereto.

The first upper interlayer insulating layer 155 may be disposed on the first etching stop layer 150. The first upper interlayer insulating layer 155 may be disposed on the sidewalls of each of the first, second, and third capping patterns 131, 132, and 133. The first upper interlayer insulating layer 155 may cover each of the first and second source/drain regions SD1 and SD2 on the field insulating layer 105. For example, the top surface of the first upper interlayer insulating layer 155 may be formed on the same plane as the top surfaces of the first, second, and third capping patterns 131, 132, and 133. The first upper interlayer insulating layer 155 may include, for example, at least one of silicon oxide, silicon nitride, silicon oxynitride, or a low-k material.

The upper source/drain contact UCA may be disposed between the first and second gate electrodes G1 and G2. The upper source/drain contact UCA may be disposed above the first source/drain region SD1. The upper source/drain contact UCA may extend into the first source/drain region SD1 by penetrating the first upper interlayer insulating layer 155 and the first etching stop layer 150 in the vertical direction DR3. The upper source/drain contact UCA may be electrically connected to the first source/drain region SD1. In FIG. 2, the upper source/drain contact UCA is illustrated as being formed as a single layer, but example embodiments of the present disclosure are not limited thereto. In some example embodiments, the upper source/drain contact UCA may be formed as a multilayer.

For example, the top surface of the upper source/drain contact UCA may be formed on the same plane as the top surface of the first upper interlayer insulating layer 155, but example embodiments of the present disclosure are not limited thereto. In some example embodiments, the top surface of the upper source/drain contact UCA may be formed higher than the top surface of the first upper interlayer insulating layer 155. The upper source/drain contact UCA may include a conductive material.

The upper silicide layer USL may be disposed between the upper source/drain contact UCA and the first source/drain region SD1. The upper silicide layer USL may be disposed along the boundary between the upper source/drain contact UCA and the first source/drain region SD1. For example, the upper silicide layer USL may include a metal silicide material.

The gate contact CB may be located above the second gate electrode G2. The gate contact CB may be connected to the second gate electrode G2 by penetrating the second capping pattern 132 in the vertical direction DR3. In FIG. 3, the gate contact CB is illustrated as being formed as a single layer, but example embodiments of the present disclosure are not limited thereto. In some example embodiments, the gate contact CB may be formed as a multilayer. For example, the top surface of the gate contact CB may be formed on the same plane as the top surfaces of the upper source/drain contact UCA and the first upper interlayer insulating layer 155, but example embodiments of the present disclosure are not limited thereto. The gate contact CB may include a conductive material.

The lower source/drain contact BCA may be disposed between the second and third gate electrodes G2 and G3. The lower source/drain contact BCA may be disposed below the second source/drain region SD2. The lower source/drain contact BCA may extend into the second source/drain region SD2 by penetrating part of the first lower interlayer insulating layer 100 and the insulating pattern 101 in the vertical direction DR3. The lower source/drain contact BCA may be electrically connected to the second source/drain region SD2. For example, the lower source/drain contact BCA may be formed as a single layer, but example embodiments of the present disclosure are not limited thereto. In some example embodiments, the lower source/drain contact BCA may be formed as a multilayer.

For example, the top surface of the lower source/drain contact BCA may be formed higher than the top surface of the insulating pattern 101. Additionally, the top surface of the lower source/drain contact BCA may be formed higher than the top surfaces of the lowermost nanosheets of the second and third plurality of nanosheets NW2 and NW3. The bottom surface of the lower source/drain contact BCA may be formed on the same plane as the bottom surface of the first sacrificial pattern 103.

For example, the width, in the first horizontal direction DR1, of the lower source/drain contact BCA may be less than the width, in the first horizontal direction DR1, of the second source/drain region SD2. The lower source/drain contact BCA may be spaced apart from each of the insulating pattern 101 and the first lower interlayer insulating layer 100 in the first horizontal direction DR1. That is, the lower source/drain contact BCA does not touch either the insulating pattern 101 and/or the first lower interlayer insulating layer 100. The lower source/drain contact BCA may include a conductive material.

The lower silicide layer BSL may be disposed between the lower source/drain contact BCA and the second source/drain region SD2. The lower silicide layer BSL may be disposed along the boundary between the lower source/drain contact BCA and the second source/drain region SD2. The lower silicide layer BSL may include, for example, a metal silicide material.

The lower via BV may be disposed below the lower source/drain contact BCA. For example, the lower via BV may be disposed within the first lower interlayer insulating layer 100. The bottom surface of the lower via BV may be formed on the same plane as the bottom surface of the first lower interlayer insulating layer 100, but example embodiments of the present disclosure are not limited thereto. For example, the width, in the first horizontal direction DR1, of the top surface of the lower via BV may be greater than the width, in the first horizontal direction DR1, of the bottom surface of the lower source/drain contact BCA. Similarly, the width, in the second horizontal direction DR2, of the top surface of the lower via BV may be greater than the width, in the second horizontal direction DR2, of the bottom surface of the lower source/drain contact BCA. For example, the width, in the first horizontal direction DR1, of the lower via BV may gradually decrease closer to the bottom surface of the lower source/drain contact BCA.

At least part of the top surface of the lower via BV may be in contact with the first lower interlayer insulating layer 100. For example, at least part of the top surface of the lower via BV on both sides, in the first horizontal direction DR1, of the lower source/drain contact BCA may be in contact with the first lower interlayer insulating layer 100. For example, the lower via BV may be integrally formed with the lower source/drain contact BCA. That is, the lower via BV and the lower source/drain contact BCA may be formed through the same manufacturing process. The lower via BV may include a conductive material. The lower via BV may include the same material as the lower source/drain contact BCA.

The first insulating liner layer 161 may be disposed between the lower source/drain contact BCA and each of the first lower interlayer insulating layer 100 and the insulating pattern 101. For example, the top surface of the first insulating liner layer 161 may be formed lower than the top surface of the lower source/drain contact BCA. For example, the bottom surface of the first insulating liner layer 161 may be formed on the same plane as the bottom surface of the lower source/drain contact BCA. For example, the first insulating liner layer 161 may be in contact with the first lower interlayer insulating layer 100, the insulating pattern 101, and the lower source/drain contact BCA. For example, the bottom surface of the first insulating liner layer 161 may be in contact with the top surface of the lower via BV. For example, the top surface of the first insulating liner layer 161 may be in contact with the lower silicide layer BSL. For example, the first insulating liner layer 161 may be conformally formed.

The second insulating liner layer 162 may be disposed on the sidewalls of the lower via BV. The second insulating liner layer 162 may be disposed between the lower via BV and the first lower interlayer insulating layer 100. For example, the top surface of the second insulating liner layer 162 may be formed on the same plane as the top surface of the lower via BV. Similarly, the bottom surface of the second insulating liner layer 162 may be formed on the same plane as the bottom surface of the lower via BV. For example, the second insulating liner layer 162 may be in contact with the sidewalls of the lower via BV and the first lower interlayer insulating layer 100. For example, the top surface of the second insulating liner layer 162 may be in contact with the first lower interlayer insulating layer 100.

For example, the first and second insulating liner layers 161 and 162 may include the same material. The first and second insulating liner layers 161 and 162 may include a different material from the first lower interlayer insulating layer 100 and the insulating pattern 101. The first and second insulating liner layers 161 and 162 may include an insulating material. For example, the first and second insulating liner layers 161 and 162 may include of SiN, SiCN, SiON, or SiOCN.

The second etching stop layer 170 may be disposed on the top surfaces of the upper source/drain contact UCA, the first, second, and third capping patterns 131, 132, and 133, and the first upper interlayer insulating layer 155. In FIGS. 2 and 3, the second etching stop layer 170 is illustrated as being formed as a single layer, but example embodiments of the present disclosure are not limited thereto. In some example embodiments, the second etching stop layer 170 may be formed as a multilayer. The second etching stop layer 170 may include, for example, at least one of aluminum oxide, aluminum nitride, hafnium oxide, zirconium oxide, silicon oxide, silicon nitride, silicon oxynitride, or a low-k material. The second upper interlayer insulating layer 175 may be disposed on the second etching stop layer 170. The second upper interlayer insulating layer 175 may include at least one of silicon oxide, silicon nitride, silicon oxynitride, or a low-k material.

The first via V1 may be connected to the upper source/drain contact UCA by penetrating the second upper interlayer insulating layer 175 and the second etching stop layer 170 in the vertical direction DR3. Similarly, the second via V2 may be connected to the gate contact CB by penetrating the second upper interlayer insulating layer 175 and the second etching stop layer 170 in the vertical direction DR3. In FIGS. 2 and 3, the first and second vias V1 and V2 are illustrated as being formed as single layers, but example embodiments of the present disclosure are not limited thereto. In some example embodiments, the first and second vias V1 and V2 may be formed as multilayers. The first and second vias V1 and V2 may include a conductive material.

A method of manufacturing a semiconductor device according to an example embodiment of the present disclosure will hereinafter be described with reference to FIGS. 2 through 24.

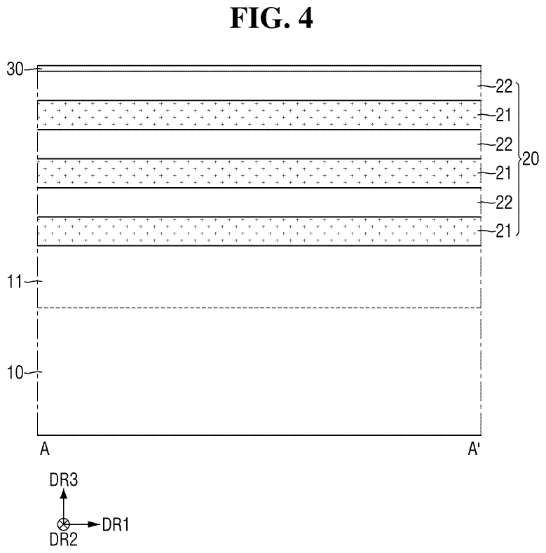

FIGS. 4 through 24 are cross-sectional views for explaining intermediate steps of a method of fabricating a semiconductor device according to an example embodiment of the present disclosure.

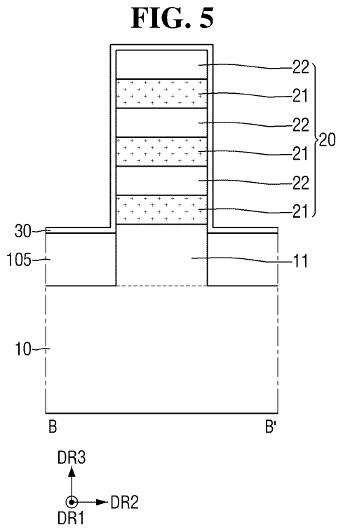

Referring to FIGS. 4 and 5, a substrate 10 may be provided. The substrate 10 may be a Si substrate or a silicon-on-insulator (SOI) substrate. In some example embodiments, the substrate 10 may include SiGe, silicon germanium-on-insulator (SGOI), indium antimonide, lead telluride compounds, indium arsenide, indium phosphide, gallium arsenide, or gallium antimonide, but example embodiments of the present disclosure are not limited thereto.

Thereafter, a stacked structure 20 may be formed on the top surface of the substrate 10. The stacked structure 20 may include first semiconductor layers 21 and second semiconductor layers 22, which are stacked on the top surface of the substrate 10 and are alternating with the first semiconductor layers 21. For example, the first semiconductor layers 21 may be formed at the bottom of the stacked structure 20, and the second semiconductor layers 22 may be formed at the top of the second semiconductor layer 22. However, example embodiments of the present disclosure are not limited to this. In some example embodiments, the first semiconductor layers 21 may be formed at the top of the stacked structure 20. The first semiconductor layers 21 may include, for example, SiGe. The second semiconductor layers 22 may include, for example, Si.

Thereafter, part of the stacked structure 20 may be etched. During the etching of the stacked structure 20, part of the substrate 10 may also be etched. Through this etching process, an active pattern 11 may be defined on the top surface of the substrate 10, below the stacked structure 20. The active pattern 11 may protrude from the top surface of the substrate 10 in the vertical direction DR3. The active pattern 11 may extend in the first horizontal direction DR1.

Thereafter, a field insulating layer 105 may be formed on the top surface of the substrate 10. The field insulating layer 105 may surround the sidewalls of the active pattern 11. For example, the top surface of the active pattern 11 may be formed higher than the top surface of the field insulating layer 105. Thereafter, a pad oxide layer 30 may be formed to cover the top surface of the field insulating layer 105, the exposed sidewalls of the active pattern 11, and the sidewalls and top surface of the stacked structure 20. For example, the pad oxide layer 30 may be conformally formed. The pad oxide layer 30 may include, for example, SiO₂.

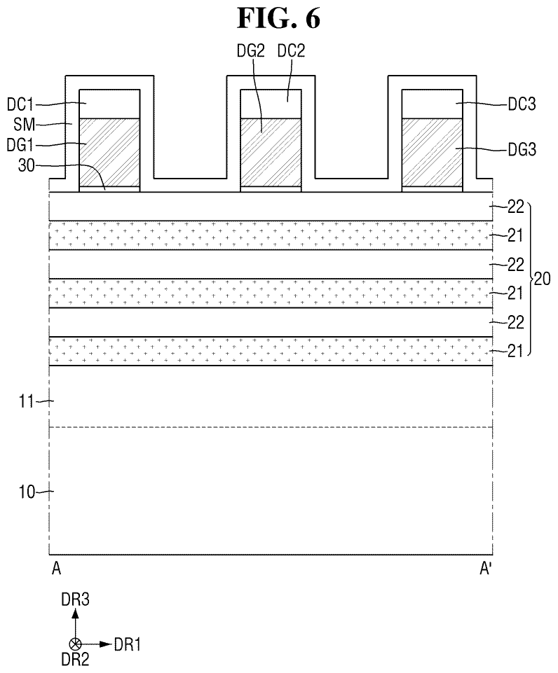

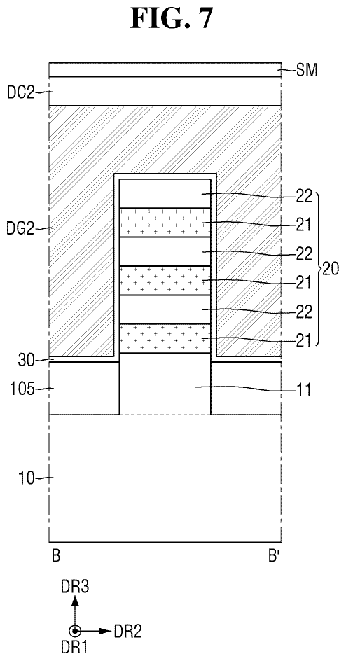

Referring to FIGS. 6 and 7, first, second, and third dummy gates DG1, DG2, and DG3, which extend in the second horizontal direction DR2, and first, second, and third dummy capping patterns DC1, DC2, and DC3, which also extend in the second horizontal direction DR2, may be formed on the pad oxide layer 30, on the stacked structure 20 and the field insulating layer 105. For example, the second dummy gate DG2 may be spaced apart from the first dummy gate DG1 in the first horizontal direction DR1, and the third dummy gate DG3 may be spaced from the second dummy gate DG2 in the first horizontal direction DR1. The first dummy capping pattern DC1 may be disposed on the first dummy gate DG1. The second dummy capping pattern DC2 may be disposed on the second dummy gate DG2. The third dummy capping pattern DC3 may be disposed on the third dummy gate DG3.

During the formation of the first, second, and third dummy gates DG1, DG2, and DG3 and the first, second, and third dummy capping patterns DC1, DC2, and DC3, the entire pad oxide layer 30, except for portions that overlap with the first, second, and third dummy gates DG1, DG2, and DG3 in the vertical direction DR3, may be removed.

Thereafter, a spacer material layer SM may be formed to cover the sidewalls and top surfaces of the first, second, and third dummy gates DG1, DG2, and DG3, the first, second, and third dummy capping patterns DC1, DC2, and DC3, the exposed sidewalls and top surfaces of the stacked structure 20, and the top surface of the field insulating layer 105. For example, the spacer material layer SM may be conformally formed. The spacer material layer SM may include, for example, SiN, SiON, SiO₂, SiOCN, SiBN, SiOBN, SiOC, or a combination thereof.

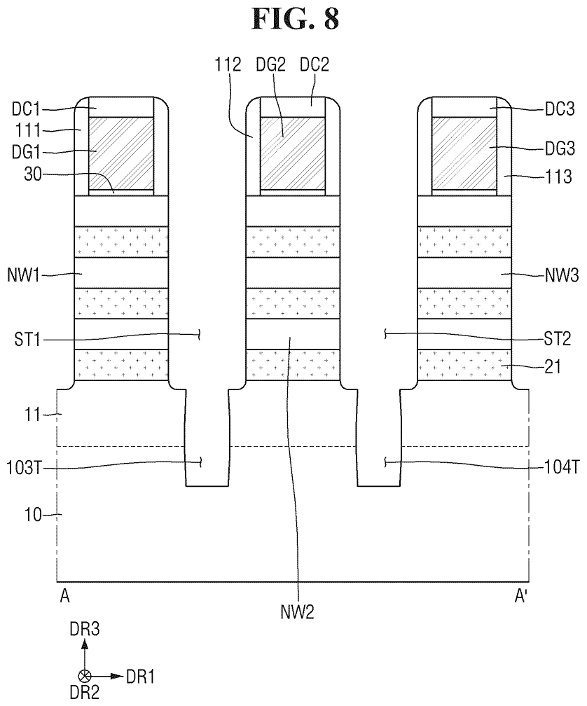

Referring to FIG. 8, first and second source/drain trenches ST1 and ST2 may be formed by etching the stacked structure 20 of FIG. 6 using the first, second, and third dummy gates DG1, DG2, and DG3 and the first, second, and third dummy capping patterns DC1, DC2, and DC3 as a mask. The first source/drain trench ST1 may be formed between the first and second dummy gates DG1 and DG2. The second source/drain trench ST2 may be formed between the second and third dummy gates DG2 and DG3.

Furthermore, a first sacrificial pattern trench 103T may be formed below the first source/drain trench ST1, and a second sacrificial pattern trench 104T may be formed below the second source/drain trench ST2. The first and second sacrificial pattern trenches 103T and 104T may be formed within each of the active pattern 11 and the substrate 10. The substrate 10 may be exposed at the bottoms of the first and second sacrificial pattern trenches 103T and 104T.

During the formation of the first and second source/drain trenches ST1 and ST2, the spacer material layer SM formed on the top surfaces of the first, second, and third dummy capping patterns DC1, DC2, and DC3 and parts of the first, second, and third dummy capping patterns DC1, DC2, and DC3 may be removed. The remaining spacer material layer SM on the sidewalls of each of the first, second, and third dummy gates DG1, DG2, and DG3 and on the sidewalls of each of the first, second, and third dummy capping patterns DC1, DC2, and DC3 may be defined as first gate spacers 111, second gate spacers 112, and third gate spacers 113.

For example, after the formation of the first and second source/drain trenches ST1 and ST2, the remaining second semiconductor layers 22 below the first dummy gate DG1 on the active pattern 11 may be defined as a first plurality of nanosheets NW1. Similarly, the remaining second semiconductor layers 22 below the second dummy gate DG2 on the active pattern 11 may be defined as a second plurality of nanosheets NW2, and the remaining second semiconductor layers 22 below the third dummy gate DG3 on the active pattern 11 may be defined as a third plurality of nanosheets NW3.

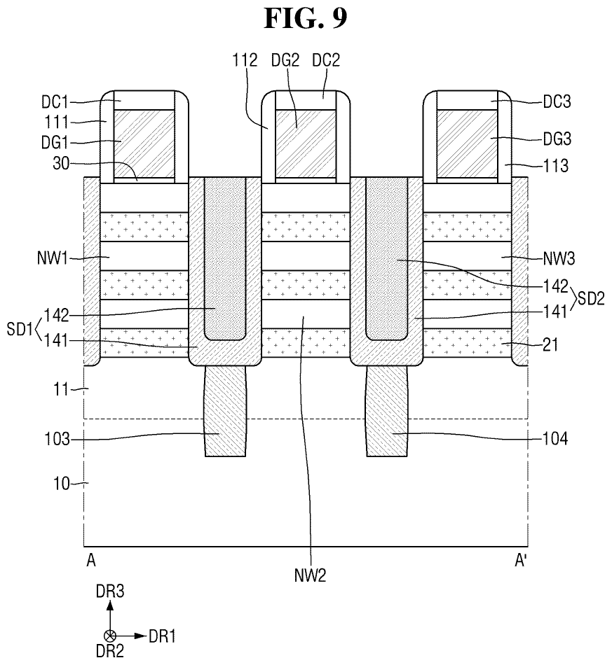

Referring to FIG. 9, a first sacrificial pattern 103 may be formed within the first sacrificial pattern trench 103T, and a second sacrificial pattern 104 may be formed within the second sacrificial pattern trench 104T. The top surfaces of the first and second sacrificial patterns 103 and 104 may be formed lower than the bottom surface of the lowermost first semiconductor layer 21. The first and second sacrificial patterns 103 and 104 may include, for example, SiGe. Thereafter, the first source/drain region SD1 may be formed within the first source/drain trench ST1, and the second source/drain region SD2 may be formed within the second source/drain trench ST2. For example, the bottom surface of the first source/drain region SD1 may be in contact with the top surface of the first sacrificial pattern 103, and the bottom surface of the second source/drain region SD2 may be in contact with the top surface of the second sacrificial pattern 104.

Each of the first and second source/drain regions SD1 and SD2 may include first and second layers 141 and 142. For example, the first layer 141 may be formed along the sidewalls and bottom surfaces of each of the first and second source/drain trenches ST1 and ST2. The first layer 141 may be in contact with the top surfaces of the first and second sacrificial patterns 103 and 104. For example, the second layer 142 may be formed on the first layer 141 to fill the rest of each of the first and second source/drain trenches ST1 and ST2.

For example, the first and second layers 141 and 142 may include SiGe. The concentration of Ge in the first and second sacrificial patterns 103 and 104 may be higher than the concentration of Ge in the first layer 141. Furthermore, the concentration of Ge in the second layer 142 may be greater than the concentration of Ge in the first and second sacrificial patterns 103 and 104.

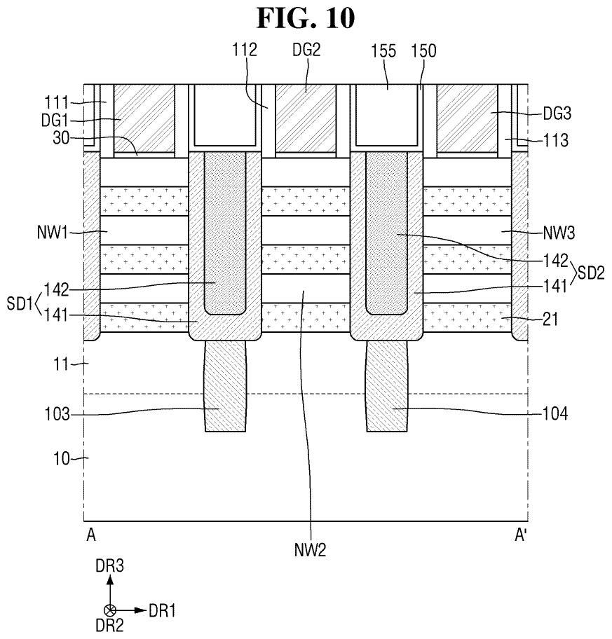

Referring to FIG. 10, a first etching stop layer 150 may be formed on the exposed top surface of the field insulating layer 105, the exposed sidewalls of each of the first, second, and third gate spacers 111, 112, and 113, the exposed top surfaces of the first, second, and third dummy capping patterns DC1, DC2, and DC3, and the exposed surfaces of the first and second source/drain regions SD1 and SD2. Thereafter, a first upper interlayer insulating layer 155 may be formed on the first etching stop layer 150. Thereafter, the top surfaces of the first, second, and third dummy gates DG1, DG2, and DG3 may be exposed through a planarization process.

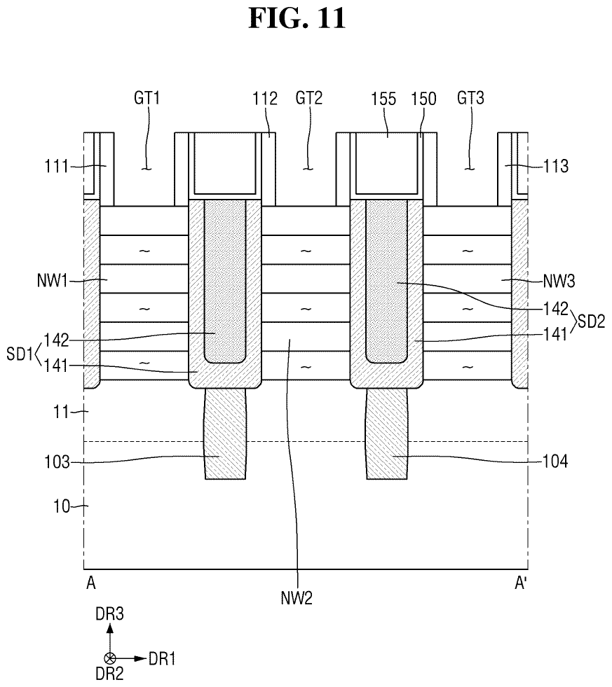

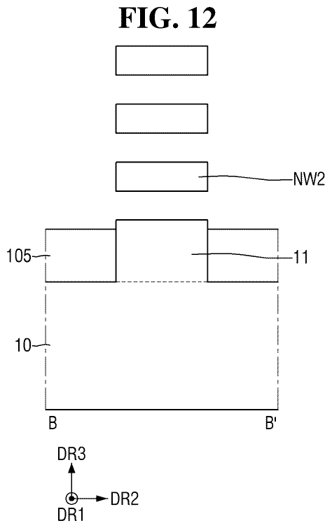

Referring to FIGS. 11 and 12, the first, second, and third dummy gates DG1, DG2, and DG3, the pad oxide layer 30, and the first semiconductor layers 21 may each be etched. The part from which the first dummy gate DG1, the pad oxide layer 30, and the first semiconductor layers 21 are etched may be defined as a first gate trench GT1. Similarly, the part from which the second dummy gate DG2, the pad oxide layer 30, and the first semiconductor layers 21 are etched may be defined as a second gate trench GT2. The part from which the third dummy gate DG3, the pad oxide layer 30, and the first semiconductor layers 21 are etched may be defined as a third gate trench GT3.

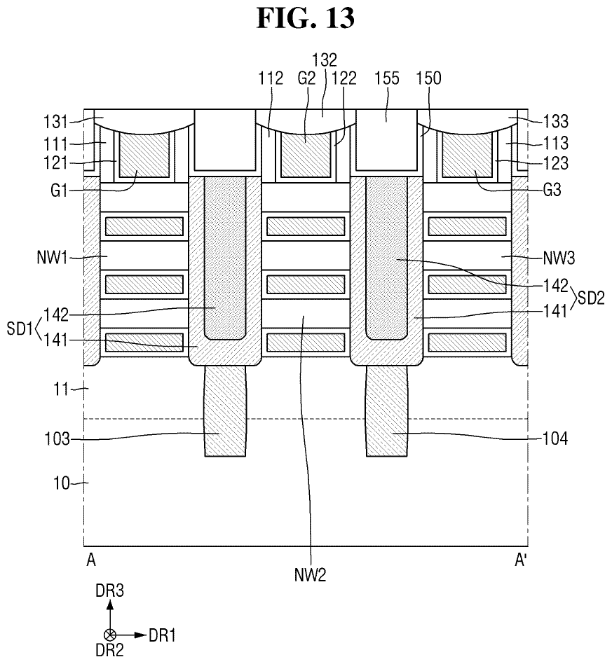

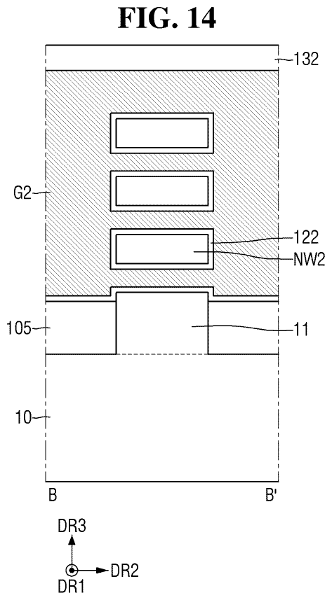

Referring to FIGS. 13 and 14, a first gate insulating layer 121, a first gate electrode G1, and a first capping pattern 131 may be sequentially formed in the first gate trench GT1. Similarly, a second gate insulating layer 122, a second gate electrode G2, and a second capping pattern 132 may be sequentially formed in the second gate trench GT2, and a third gate insulating layer 123, a third gate electrode G3, and a third capping pattern 133 may be sequentially formed in the third gate trench GT3.

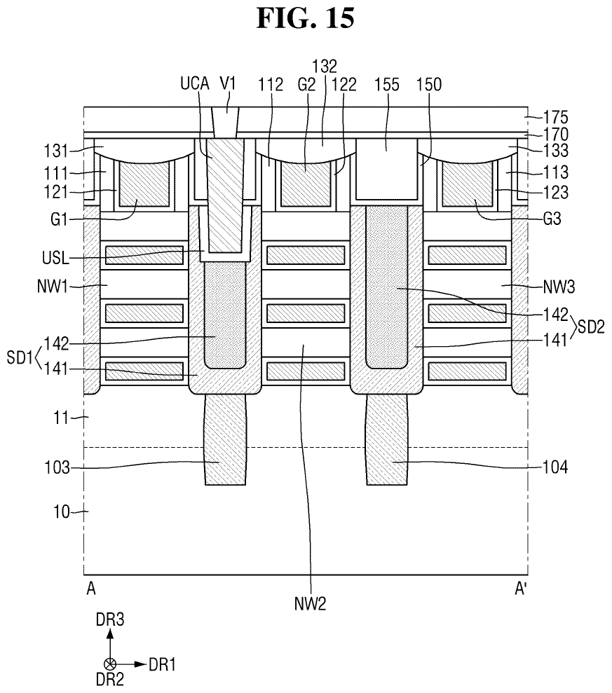

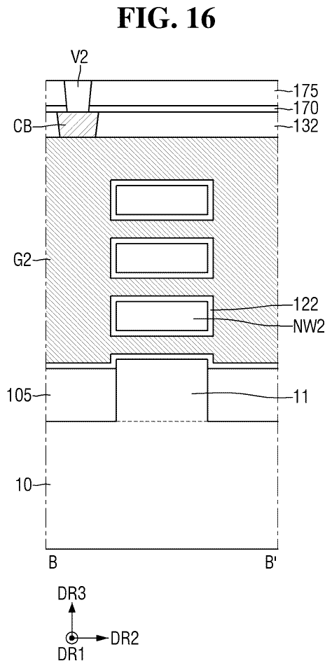

Referring to FIGS. 15 and 16, an upper source/drain contact UCA may be formed on the first source/drain region SD1. The upper source/drain contact UCA may extend into the first source/drain region SD1 by penetrating the first upper interlayer insulating layer 155 and the first etching stop layer 150 in the vertical direction DR3. Additionally, an upper silicide layer USL may be formed between the first source/drain region SD1 and the upper source/drain contact UCA. Furthermore, a gate contact CB, which is connected to the second gate electrode G2 by penetrating the second capping pattern 132 in the vertical direction DR3, may be formed.

Thereafter, a second etching stop layer 170 and a second upper interlayer insulating layer 175 may be sequentially formed on the top surfaces of the first upper interlayer insulating layer 155, the first, second, and third capping patterns 131, 132, and 133, and the upper source/drain contact UCA. Thereafter, a first via V1, which is connected to the upper source/drain contact UCA by penetrating the second etching stop layer 170 and the second upper interlayer insulating layer 175 in the vertical direction DR3, may be formed. Similarly, a second via V2, which is connected to the gate contact CB by penetrating the second etching stop layer 170 and the second upper interlayer insulating layer 175 in the vertical direction DR3, may be formed.

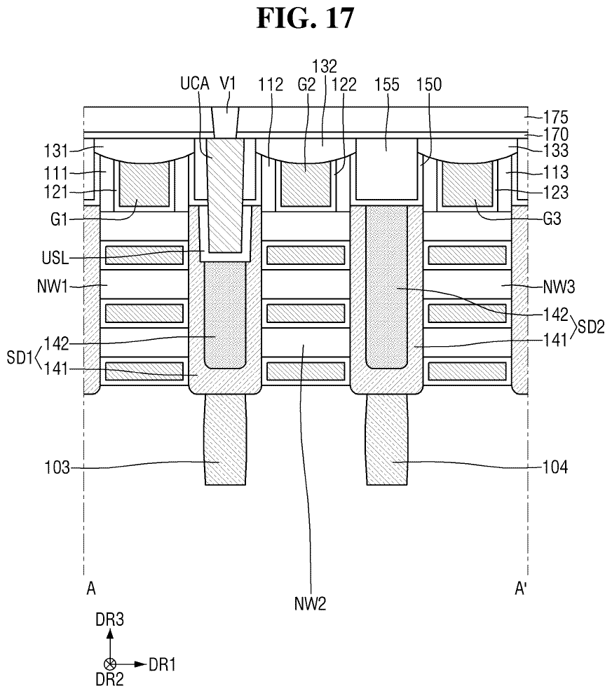

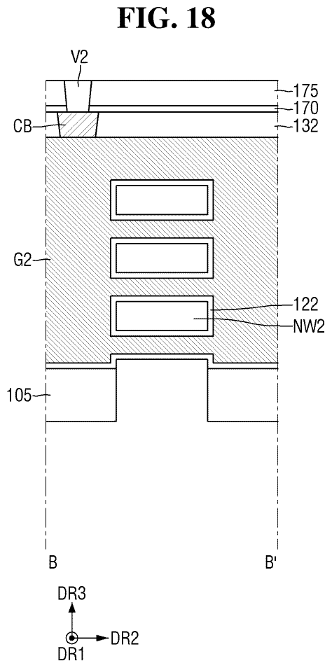

Referring to FIGS. 17 and 18, parts of the substrate 10 and the active pattern 11 may be etched. Thus, parts of the first, second, and third gate insulating layers 121, 122, and 123, parts of the first and second source/drain regions SD1 and SD2, part of the field insulating layer 105, and parts of the first and second sacrificial patterns 103 and 104 may be exposed.

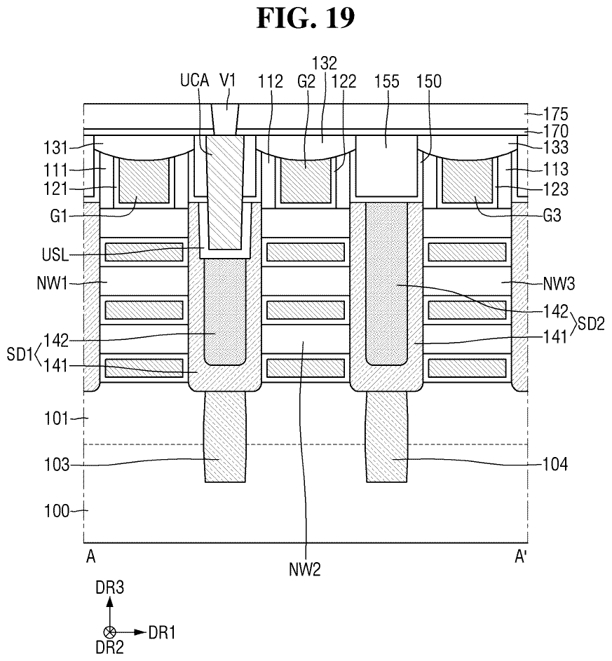

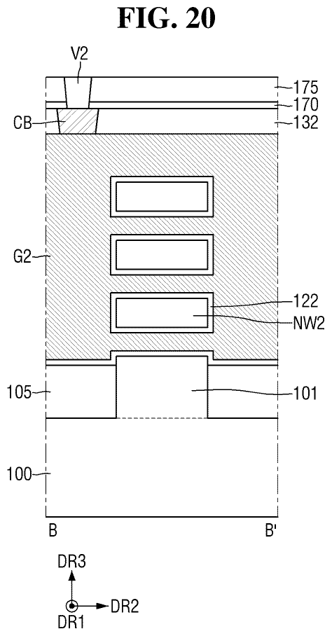

Referring to FIGS. 19 and 20, a first lower interlayer insulating layer 100 and an insulating pattern 101 may be formed in the parts from which the substrate 10 and the active pattern 11 have been etched. For example, the insulating pattern 101 may be formed in the part from which the active pattern 11 has been etched. The insulating pattern 101 may be in contact with the first, second, and third gate insulating layers 121, 122, and 123, the first and second source/drain regions SD1 and SD2, the field insulating layer 105, and the first and second sacrificial patterns 103 and 104. The insulating pattern 101 may surround parts of the sidewalls of each of the first and second sacrificial patterns 103 and 104.

Additionally, a first lower interlayer insulating layer 100 may be formed in the part from which the substrate 10 has been etched. The first lower interlayer insulating layer 100 may be in contact with the field insulating layer 105 and each of the first and second sacrificial patterns 103 and 104. The first lower interlayer insulating layer 100 may surround parts of the sidewalls of each of the first and second sacrificial patterns 103 and 104. The first lower interlayer insulating layer 100 may cover the bottom surfaces of the first and second sacrificial patterns 103 and 104.

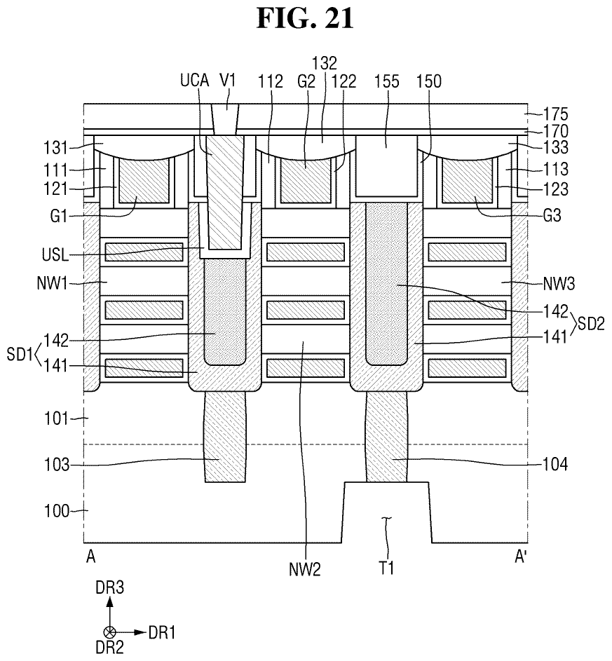

Referring to FIG. 21, a first trench T1 may be formed on the bottom surface of the second sacrificial pattern 104. For example, through the first trench T1, the bottom surface of the second sacrificial pattern 104 may be exposed. For example, the width, in the first horizontal direction DR1, of the top surface of the first trench T1 may be greater than the width, in the first horizontal direction DR1, of the bottom surface of the second sacrificial pattern 104.

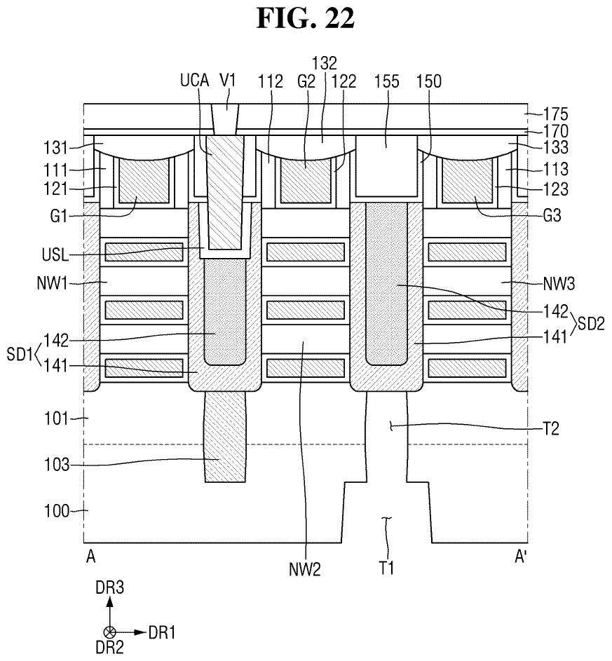

Referring to FIG. 22, the second sacrificial pattern 104 may be wet-etched through the first trench T1. The etched part of the second sacrificial pattern 104 may be defined as a second trench T2. Through the second trench T2, the first layer 141 may be exposed. As the concentration of Ge in the second sacrificial pattern 104 is greater than the concentration of Ge in the first layer 141, the second sacrificial pattern 104 may be selectively etched. Accordingly, the first layer 141 may be mitigated or prevented from being etched during the etching of the second sacrificial pattern 104.

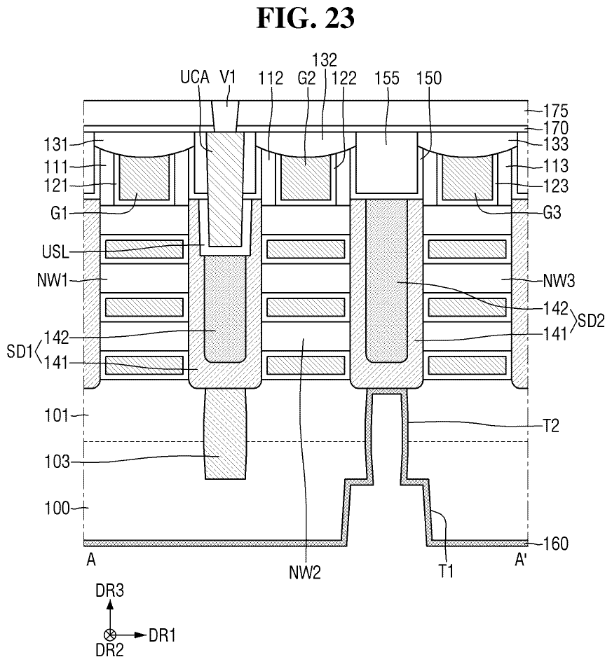

Referring to FIG. 23, an insulating liner material layer 160 may be formed on the sidewalls and top surface of the first trench T1, the sidewalls and top surface of the second trench T2, and the bottom surface of the first lower interlayer insulating layer 100. For example, the insulating liner material layer 160 may be conformally formed. For example, the insulating liner material layer 160 may include one of SiN, SiCN, SiON, and SiOCN.

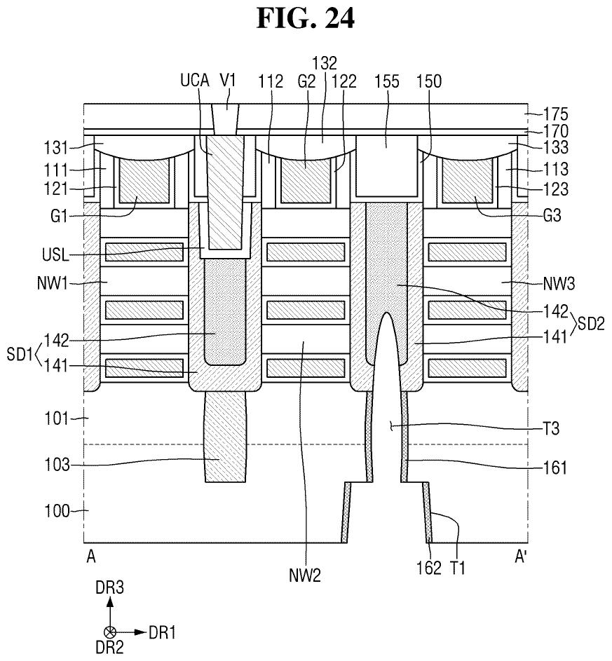

Referring to FIG. 24, by performing an etching process, portions of the insulating liner material layer 160 formed on the top surface of the first trench T1, the top surface of the second trench T2, and the bottom surface of the first lower interlayer insulating layer 100 may be etched. During the etching of the portion of the insulating liner material layer 160 on the top surface of the second trench T2, the second source/drain region SD2 may also be partially etched. Thus, a third trench T3 may be formed on the top surface of the first trench T1.

For example, the top surface of the third trench T3 may be formed higher than the top surfaces of the lowermost nanosheets of the second and third plurality of nanosheets NW2 and NW3. Part of the insulating liner material layer 160 that remains on the sidewalls of the third trench T3 may be defined as a first insulating liner layer 161. Additionally, another part of the insulating liner material layer 160 that remains on the sidewalls of the first trench T1 may be defined as a second insulating liner layer 162.

Referring to FIGS. 2 and 3, a lower source/drain contact BCA may be formed in the third trench T3. The top surface of the lower source/drain contact BCA may be formed higher than the top surfaces of the lowermost nanosheets of the second and third plurality of nanosheets NW2 and NW3. Also, a lower via BV may be formed in the first trench T1. The lower source/drain contact BCA and the lower via BV may be formed through the same manufacturing process. For example, the lower source/drain contact BCA and the lower via BV may be integrally formed.

Furthermore, a lower silicide layer BSL may be formed between the lower source/drain contact BCA and the second source/drain region SD2. For example, the top surface of the first insulating liner layer 161 may be in contact with the lower silicide layer BSL. In this manner, the semiconductor device of FIGS. 2 and 3 may be fabricated.

The method of manufacturing a semiconductor device according to this example embodiment of the present disclosure may utilize the second sacrificial pattern 104 as a sacrificial layer to form the lower source/drain contact BCA. By forming the concentration of Ge higher in the second sacrificial pattern 104 than in the first layer 141 of the second source/drain region SD2, the second sacrificial pattern 104 may be selectively wet-etched. Thus, the first layer 141 may be mitigated or prevented from being etched while the second sacrificial pattern 104 is being wet-etched, thereby protecting the second source/drain region SD2. Moreover, the method of manufacturing a semiconductor device according to this example embodiment of the present disclosure may form the lower source/drain contact BCA, which extends into the second source/drain region SD2, by forming the first insulating liner layer 161 in the etched part of the second sacrificial pattern 104 and then performing a subsequent etching process.

In a semiconductor device manufactured by the method of manufacturing a semiconductor device according to this example embodiment of the present disclosure, the top surface of the lower source/drain contact BCA may be formed higher than the top surfaces of the lowermost nanosheets of the second and third plurality of nanosheets NW2 and NW3. Thus, the reliability of the electrical connection between the lower source/drain contact BCA and the second source/drain region SD2 may be enhanced. Additionally, the top surfaces of portions of the first insulating liner layer 161 on the sidewalls of the lower source/drain contact BCA may be in contact with the lower silicide layer BSL.

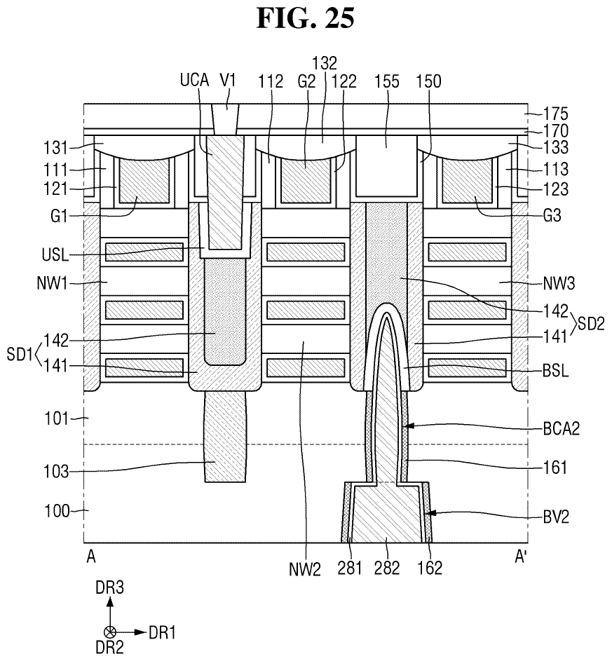

A semiconductor device according to another example embodiment of the present disclosure will hereinafter be described with reference to FIG. 25, focusing mainly on the differences from the semiconductor device of FIGS. 1 through 3.

FIG. 25 is a cross-sectional view for explaining a semiconductor device according to an example embodiment of the present inventive concepts.

Referring to FIG. 25, a lower source/drain contact BCA2 and a lower via BV2 may be formed as double films.

For example, each of the lower source/drain contact BCA2 and the lower via BV2 may include a contact barrier layer 281 and a contact filling layer 282. The contact barrier layer 281 of the lower source/drain contact BCA2 may form the sidewalls and the top surface of the source/drain contact BCA2. The contact barrier layer 281 of the lower source/drain contact BCA2 may be in contact with each of a first insulating liner layer 161 and a lower silicide layer BSL. The contact filling layer 282 of the lower source/drain contact BCA2 may fill the space between portions of the contact barrier layer 281 of the lower source/drain contact BCA2.

The contact barrier layer 281 of the lower via BV2 may form parts of the sidewalls and the top surface of the lower via BV2. The contact barrier layer 281 of the lower via BV2 may be in contact with the first insulating liner layer 161, a second insulating liner layer 162, and a first lower interlayer insulating layer 100. The contact filling layer 282 of the lower via BV2 may fill the space between portions of the contact barrier layer 281 of the lower via BV2.

For example, the lower source/drain contact BCA2 and the lower via BV2 may be integrally formed. The contact barrier layer 281 of the lower source/drain contact BCA2 and the contact barrier layer 281 of the lower via BV2 may be integrally formed. That is, the contact barrier layer 281 of the lower source/drain contact BCA2 and the contact barrier layer 281 of the lower via BV2 may be continuously formed. Similarly, the contact filling layer 282 of the lower source/drain contact BCA2 and the contact filling layer 282 of the lower via BV2 may be integrally formed. That is, the contact barrier layer 281 of the lower source/drain contact BCA2 and the contact barrier layer 281 of the lower via BV2 may be formed continuously may be continuously formed.

The contact barrier layer 281 may include a material such as Ta, TaN, Ti, TiN, Ru, Co, Ni, nickel boron (NiB), W, WN, tungsten carbide nitride (WCN), Zr, zirconium nitride (ZrN), V, vanadium nitride (VN), Nb, NbN, Pt, Ir, or Rh. The contact filling layer 282 may include a material such as Al, W, Co, Ru, or Mo.

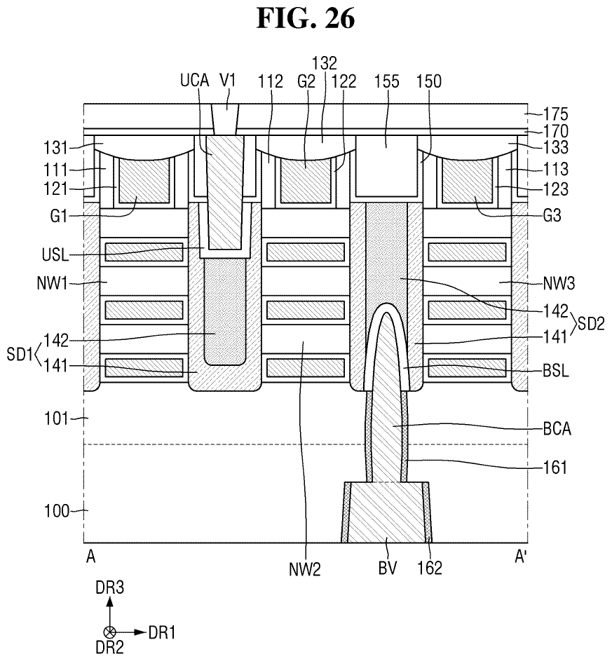

A semiconductor device according to another example embodiment of the present disclosure will hereinafter be described with reference to FIG. 26, focusing mainly on the differences from the semiconductor device of FIGS. 1 through 3.

FIG. 26 is a cross-sectional view for explaining a semiconductor device according to an example embodiment of the present inventive concepts.

Referring to FIG. 26, no first sacrificial pattern (“103” of FIG. 2) may be disposed below a first source/drain region SD1. For example, the bottom surface of the first source/drain region SD1 may generally be in contact with an insulating pattern 101.

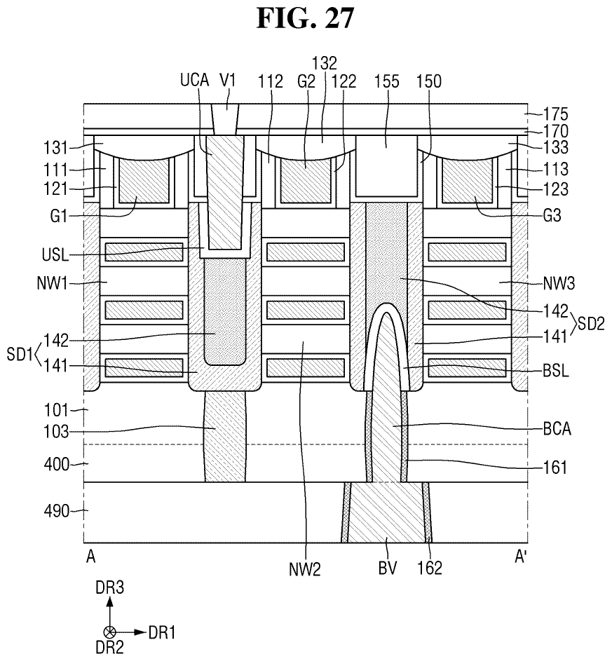

A semiconductor device according to another example embodiment of the present disclosure will hereinafter be described with reference to FIG. 27, focusing mainly on the differences from the semiconductor device of FIGS. 1 through 3.

FIG. 27 is a cross-sectional view for explaining a semiconductor device according to an example embodiment of the present inventive concepts.

Referring to FIG. 27, a second lower interlayer insulating layer 490 may be disposed below a first lower interlayer insulating layer 400, and a lower via BV may be disposed in the second lower interlayer insulating layer 490.

For example, the second lower interlayer insulating layer 490 may be disposed on the bottom surface of the first lower interlayer insulating layer 400. The second lower interlayer insulating layer 490 may be in contact with the bottom surfaces of the first lower interlayer insulating layer 400 and a first sacrificial pattern 103. For example, the second lower interlayer insulating layer 490 may include a different material from the first lower interlayer insulating layer 400. For example, the second lower interlayer insulating layer 490 may include at least one of silicon oxide, silicon nitride, silicon oxynitride, or a low-k material.

For example, the second lower interlayer insulating layer 490 may surround the sidewalls of the lower via BV. For example, the top surface of the second lower interlayer insulating layer 490 may be formed on the same plane as the top surface of the lower via BV. For example, at least part of the top surface of the lower via BV may be in contact with the first lower interlayer insulating layer 400.

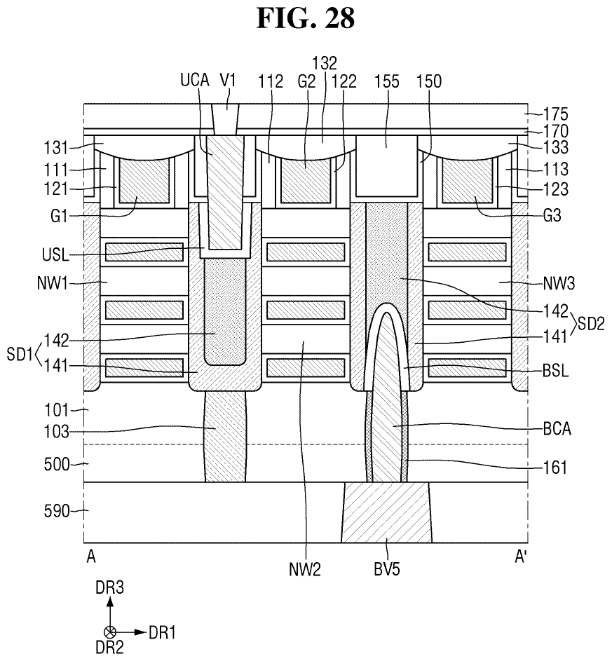

A semiconductor device according to another example embodiment of the present disclosure will hereinafter be described with reference to FIG. 28, focusing mainly on the differences from the semiconductor device of FIGS. 1 through 3.

FIG. 28 is a cross-sectional view for explaining a semiconductor device according to an example embodiment of the present inventive concepts.

Referring to FIG. 28, a second lower interlayer insulating layer 590 may be disposed below a first lower interlayer insulating layer 500, and a lower via BV5, which is disposed in the second lower interlayer insulating layer 590, may be formed as a single film.

For example, the second lower interlayer insulating layer 590 may be disposed on the bottom surface of the first lower interlayer insulating layer 500. The second lower interlayer insulating layer 590 may be in contact with both the bottom surface of the first lower interlayer insulating layer 500 and the bottom surface of a first sacrificial pattern 103. For example, the second lower interlayer insulating layer 590 may include a different material from the first lower interlayer insulating layer 500. For example, the second lower interlayer insulating layer 590 may include at least one of silicon oxide, silicon nitride, silicon oxynitride, or a low-k material.

For example, the second lower interlayer insulating layer 590 may surround the sidewalls of the lower via BV5. For example, the top surface of the second lower interlayer insulating layer 590 may be formed on the same plane as the top surface of the lower via BV5. For example, at least part of the top surface of the lower via BV5 may be in contact with the first lower interlayer insulating layer 500. In some example embodiments, top portions of the sidewalls of the lower via BV5 may be in contact with the first lower interlayer insulating layer 500. For example, the lower via BV5 may be formed as a single film. For example, the lower via BV5 may include a conductive material.

While some example embodiments have been described with reference to the attached drawings in accordance with the technical spirit of the present disclosure, it should be understood that the present disclosure is not limited to these example embodiments. The inventive concepts may be manufactured in various different forms, and those of ordinary skill in the art will appreciate that the example embodiments may be carried out in other specific forms without changing the technical spirit or essential features of the inventive concepts. Therefore, the example embodiments described above should be considered in all respects as illustrative and not restrictive.

What is claimed is:

1. A semiconductor device comprising:
a first lower interlayer insulating layer;
an insulating pattern extending in a first horizontal direction on a top surface of the first lower interlayer insulating layer;
first, second, and third gate electrodes extending in a second horizontal direction different from the first horizontal direction on the insulating pattern, the first, second, and third gate electrodes being sequentially spaced apart from one another in the first horizontal direction;
a first source/drain region between the first and second gate electrodes on the insulating pattern;
a second source/drain region between the second and third gate electrodes on the insulating pattern;
a lower source/drain contact extending into the second source/drain region by penetrating the first lower interlayer insulating layer and the insulating pattern in a vertical direction, a top of the lower source/drain contact being higher than a top surface of the insulating pattern;
a first insulating liner layer between the lower source/drain contact and each of the first lower interlayer insulating layer and the insulating pattern; and
a lower silicide layer between the second source/drain region and the lower source/drain contact, the lower silicide layer being in contact with a top surface of the first insulating liner layer.

2. The semiconductor device of claim 1, further comprising:
a first plurality of nanosheets stacked to be spaced apart from one another in the vertical direction on the insulating pattern, the first plurality of nanosheets being surrounded by the first gate electrode;
a second plurality of nanosheets stacked to be spaced apart from one another in the vertical direction on the insulating pattern, the second plurality of nanosheets spaced apart from the first plurality of nanosheets in the first horizontal direction, the second plurality of nanosheets being surrounded by the second gate electrode; and
a third plurality of nanosheets stacked to be spaced apart from one another in the vertical direction on the insulating pattern, the third plurality of nanosheets spaced apart from the second plurality of nanosheets in the first horizontal direction, the third plurality of nanosheets being surrounded by the third gate electrode.

3. The semiconductor device of claim 2, wherein the top of the lower source/drain contact is higher than a top surface of a lowermost nanosheet of the second plurality of nanosheets.

4. The semiconductor device of claim 1, further comprising:
a lower via below the lower source/drain contact, a width of a top surface of the lower via in the first horizontal direction being greater than a width of a bottom surface of the lower source/drain contact in the first horizontal direction,
wherein at least part of the top surface of the lower via is in contact with the first lower interlayer insulating layer.

5. The semiconductor device of claim 4, further comprising:
a second insulating liner layer being in contact with both sidewalls of the lower via in the first horizontal direction, the second insulating liner layer including a same material as the first insulating liner layer.

6. The semiconductor device of claim 4, wherein the lower via and the lower source/drain contact are parts of an integral body, respectively.

7. The semiconductor device of claim 4, further comprising:
a second lower interlayer insulating layer on a bottom surface of the first lower interlayer insulating layer, a top surface of the second lower interlayer insulating layer being on a same plane as the top surface of the lower via.

8. The semiconductor device of claim 1, further comprising:
an upper interlayer insulating layer covering the first and second source/drain regions on the top surface of the first lower interlayer insulating layer; and
an upper source/drain contact extending into the first source/drain region by penetrating the upper interlayer insulating layer in the vertical direction.

9. The semiconductor device of claim 1, further comprising:
a sacrificial pattern below the first source/drain region, both sidewalls of the sacrificial pattern in the first horizontal direction being in contact with each of the insulating pattern and the first lower interlayer insulating layer, the sacrificial pattern including silicon germanium (SiGe).

10. The semiconductor device of claim 9, wherein a bottom surface of the sacrificial pattern is on a same plane as a bottom surface of the lower source/drain contact.

11. The semiconductor device of claim 1, wherein the lower source/drain contact is a single film structure.

12. The semiconductor device of claim 1, wherein the lower source/drain contact includes a contact barrier layer being in contact with each of the first insulating liner layer and the lower silicide layer, and a contact filling layer filling a space between portions of the contact barrier layer.

13. A semiconductor device comprising:
a first lower interlayer insulating layer;
an insulating pattern extending in a first horizontal direction on a top surface of the first lower interlayer insulating layer;
a first plurality of nanosheets stacked to be spaced apart from one another in a vertical direction on the insulating pattern;
a second plurality of nanosheets stacked to be spaced apart from one another in the vertical direction on the insulating pattern, the second plurality of nanosheets spaced apart from the first plurality of nanosheets in the first horizontal direction;
a first gate electrode extending in a second horizontal direction different from the first horizontal direction on the insulating pattern, the first gate electrode surrounding the first plurality of nanosheets;
a second gate electrode extending in the second horizontal direction on the insulating pattern, the second gate electrode spaced apart from the first gate electrode in the first horizontal direction, the second gate electrode surrounding the second plurality of nanosheets;
a source/drain region between the first and second gate electrodes on the insulating pattern;
a lower source/drain contact extending into the source/drain region by penetrating the first lower interlayer insulating layer and the insulating pattern in the vertical direction, a top of the lower source/drain contact being higher than a top surface of a lowermost nanosheet of the first plurality of nanosheets;
a first insulating liner layer between the lower source/drain contact and each of the first lower interlayer insulating layer and the insulating pattern; and
a lower via below the lower source/drain contact, a width of a top surface of the lower via in the first horizontal direction being greater than a width of a bottom surface of the lower source/drain contact in the first horizontal direction, at least part of the top surface of the lower via being in contact with the first lower interlayer insulating layer.

14. The semiconductor device of claim 13, further comprising:
a lower silicide layer between the source/drain region and the lower source/drain contact, the lower silicide layer being in contact with a top surface of the first insulating liner layer.

15. The semiconductor device of claim 13, further comprising:
a second insulating liner layer being in contact with both sidewalls of the lower via in the first horizontal direction, the second insulating liner layer including a same material as the first insulating liner layer.

16. The semiconductor device of claim 15, wherein a top surface of the second insulating liner layer is on a same plane as the top surface of the lower via.

17. The semiconductor device of claim 13, wherein the lower via and the lower source/drain contact are parts of an integral body, respectively.

18. The semiconductor device of claim 13, further comprising:
a second lower interlayer insulating layer disposed on a bottom surface of the first lower interlayer insulating layer, a top surface of the second lower interlayer insulating layer being on same plane as the top surface of the lower via.

19. A semiconductor device comprising:
a first lower interlayer insulating layer;
an insulating pattern extending in a first horizontal direction on a top surface of the first lower interlayer insulating layer;
a first plurality of nanosheets stacked to be spaced apart from one another in a vertical direction on the insulating pattern;
a second plurality of nanosheets stacked to be spaced apart from one another in the vertical direction on the insulating pattern, the second plurality of nanosheets spaced apart from the first plurality of nanosheets in the first horizontal direction;
a third plurality of nanosheets stacked to be spaced apart from one another in the vertical direction on the insulating pattern, the third plurality of nanosheets spaced apart from the second plurality of nanosheets in the first horizontal direction;
a first gate electrode extending in a second horizontal direction different from the first horizontal direction on the insulating pattern, the first gate electrode surrounding the first plurality of nanosheets;
a second gate electrode extending in the second horizontal direction on the insulating pattern, the second gate electrode spaced apart from the first gate electrode in the first horizontal direction, the second gate electrode surrounding the second plurality of nanosheets;
a third gate electrode extending in the second horizontal direction on the insulating pattern, the third gate electrode spaced apart from the second gate electrode in the first horizontal direction, the third gate electrode surrounding the third plurality of nanosheets;
a first source/drain region between the first and second gate electrodes on the insulating pattern;
a second source/drain region between the second and third gate electrodes on the insulating pattern;
an upper interlayer insulating layer covering the first and second source/drain regions on the top surface of the first lower interlayer insulating layer;
an upper source/drain contact extending into the first source/drain region by penetrating the upper interlayer insulating layer in the vertical direction;
a lower source/drain contact extending into the second source/drain region by penetrating the first lower interlayer insulating layer and the insulating pattern in the vertical direction, a top of the lower source/drain contact being higher than a top surface of a lowermost nanosheet of the second plurality of nanosheets;
a lower via below the lower source/drain contact, a width of a top surface of the lower via in the first horizontal direction being greater than a bottom surface of the lower source/drain contact in the first horizontal direction;
a first insulating liner layer between the lower source/drain contact and each of the first lower interlayer insulating layer and the insulating pattern;
a second insulating liner layer being in contact with both sidewalls of the lower via in the first horizontal direction, the second insulating liner layer including a same material as the first insulating liner layer; and
a lower silicide layer between the second source/drain region and the lower source/drain contact, the lower silicide layer being in contact with a top surface of the first insulating liner layer.

20. The semiconductor device of claim 19, further comprising:
a sacrificial pattern below the first source/drain region, both sidewalls of the sacrificial pattern in the first horizontal direction being in contact with each of the insulating pattern and the first lower interlayer insulating layer, the sacrificial pattern including silicon germanium (SiGe),
wherein the first source/drain region includes,
a first layer being in contact with sidewalls of each of the first plurality of nanosheets and the second plurality of nanosheets in the first horizontal direction and a top surface of the sacrificial pattern, and
a second layer on the first layer, and
wherein a concentration of germanium (Ge) included in the sacrificial pattern is greater than a concentration of germanium (Ge) included in the first layer.
